(19) United States
(12) Patent Application Publication
(10) Pub. No.: US 2008/0265444 A1
(43) Pub. Date: Oct. 30, 2008

(54) THIN-FILM ALUMINUM NITRIDE ENCAPSULANT FOR METALLIC STRUCTURES ON INTEGRATED CIRCUITS AND METHOD OF FORMING SAME

(75) Inventors: James D. Parsons, Reno, NV (US); Gregg B. Kruaval, Fernley, NV (US)

Correspondence Address: KOPPEL, PATRICK & HEYBL, 555 ST. CHARLES DRIVE, SUITE 107, THOUSAND OAKS, CA, 91360, US

(73) Assignee: HEETRONIX

(21) Appl. No.: 12/107,181

(22) Filed: Apr. 22, 2008

Related U.S. Application Data
(60) Provisional application No. 60/926,677, filed on Apr. 26, 2007.

(51) Int. Cl. H01L 23/29; H05K 3/00; H01L 21/56

(52) U.S. Cl. 257/788; 427/96.4; 438/127; 438/107; 257/758; 257/E23.117; 257/E21.502

(57) ABSTRACT

An aluminum nitride (AlN) thin-film is applied over thin-film metallic circuitry such as an environmental sensor, on the side edges of electrode pads, and/or over some or all of the surface area of a substrate. The thin-film acts to protect the encapsulated structures from exposure to oxidation and from reducing and vacuum environments, electrically insulates the encapsulated structures from other structures, and helps to securely adhere the structures to the substrate surface. The AlN thin-film can also enable multiple IC layers to be stacked on top of each other, with AlN thin-film interlayers employed between IC layers such that each IC layer is separated and electrically insulated from adjacent layers.

### RELATED APPLICATIONS

This application claims the benefit of provisional patent application No. 60/926,677 to James D. Parsons and Gregg B. Kruaval, filed Apr. 26, 2007.

### BACKGROUND OF THE INVENTION

1. Field of the Invention

This invention relates generally to integrated circuits (ICs), and more particularly to means of encapsulating metallic structures formed on an IC substrate.

2. Description of the Related Art

Integrated circuits comprise a semiconductor substrate upon which are formed various structures which are interconnected to form a circuit. Signals are conveyed to and from the chip via input/output (I/O) electrode pads which connect to the on-chip circuitry; lead wires are typically soldered or welded to the electrode pads to carry the signals to and from the chip.

Some IC structures are metallic. For example, the metallization that interconnects on-chip circuits with each other and with the electrode pads, as well as the electrode pads themselves, are metallic. In some cases, the on-chip circuit itself is metallic; for example, some environmental sensors comprise a metallic structure which has a resistance that varies with a physical parameter such as pressure or temperature.

Unfortunately, the metallic structures formed on an IC may be degraded by various mechanisms. For example, process steps that follow the formation of the metallic structures may be performed at high temperatures. These high temperature steps can cause oxidation or act as a reducing or vacuum environment which may change the characteristics of the metal making up a structure. For example, for a metallic environmental sensor as described above, exposure to an oxidizing atmosphere or a reducing or vacuum environment may alter the sensor's relationship between its resistance and the sensed parameter, thereby degrading the sensor's accuracy.

Another problem can arise when there is a need to stack one or more IC layers on top of each other. In this case, when stacked, the metallic structures of one circuit layer may come into contact with those of another layer, and thereby cause the circuits on one or both layers to malfunction or fail.

### SUMMARY OF THE INVENTION

ICs which employ a aluminum nitride (AlN) thin-film as an encapsulant are presented, in which the AlN thin-film acts to protect encapsulated structures from oxidation, as well as reducing and vacuum environments.

The present thin-film encapsulant is advantageously employed over thin-film metallic circuitry such as an environmental sensor, on the vertical edges of an electrode pad, and/or over some or all of the surface area of a substrate. Structures encapsulated with the present AlN thin-film are protected from exposure to an oxidizing atmosphere and from reducing and vacuum environments, are electrically insulated from other metallic structures, and may be more securely adhered to the substrate surface.

The thin-film might also be applied over lead wires which provide connections to metallic structures on the substrate, thereby protecting them as well. Also, to enable multiple ICs to be stacked on top of each other, IC layers which support an adjacent IC layer may be electrically isolated with interlayers of thin-film AlN, such that each IC layer is separated and electrically insulated from adjacent substrates.

These and other features, aspects, and advantages of the present invention will become better understood with reference to the following drawings, description, and claims.

### BRIEF DESCRIPTION OF THE DRAWINGS

FIG. 1a is a plan view of an IC which includes a metallic circuit and electrode pads which have been encapsulated with an AlN thin-film per the present invention.

FIG. 1b is a cross-sectional view of the IC of FIG. 1a, cut along section line A-A.

FIG. 1c is a cross-sectional view of the IC of FIG. 1a, cut along section line B-B.

FIG. 1d is a cross-sectional view of the IC of FIG. 1a, cut along section line C-C.

FIG. 2a is a plan view of another IC which includes electrode pads which have been encapsulated with an AlN thin-film per the present invention.

FIG. 2b is a cross-sectional view of the IC of FIG. 2a, cut along section line D-D.

FIG. 3 is a section view of two IC layers stacked on top of each other, separated and electrically insulated from each other using an AlN thin-film interlayer per the present invention.

FIG. 4 is a flow chart illustrating one possible process sequence by which an IC in accordance with the present invention may be fabricated.

### DETAILED DESCRIPTION OF THE INVENTION

The present AlN thin-film encapsulant is advantageously employed over thin-film metallic circuitry such as an environmental sensor, on the vertical edges of an electrode pad, and/or over some or all of the surface area of an IC substrate. When used as described herein, the AlN thin-film acts to protect the encapsulated structures from exposure to an oxidizing atmosphere and from reducing and vacuum environments, electrically insulates them from other metallic structures, and may improve their adherence to the IC substrate's surface. Note, however, that to act as an effective encapsulant, the AlN thin-film must not chemically react with the conductive materials it is in contact with.

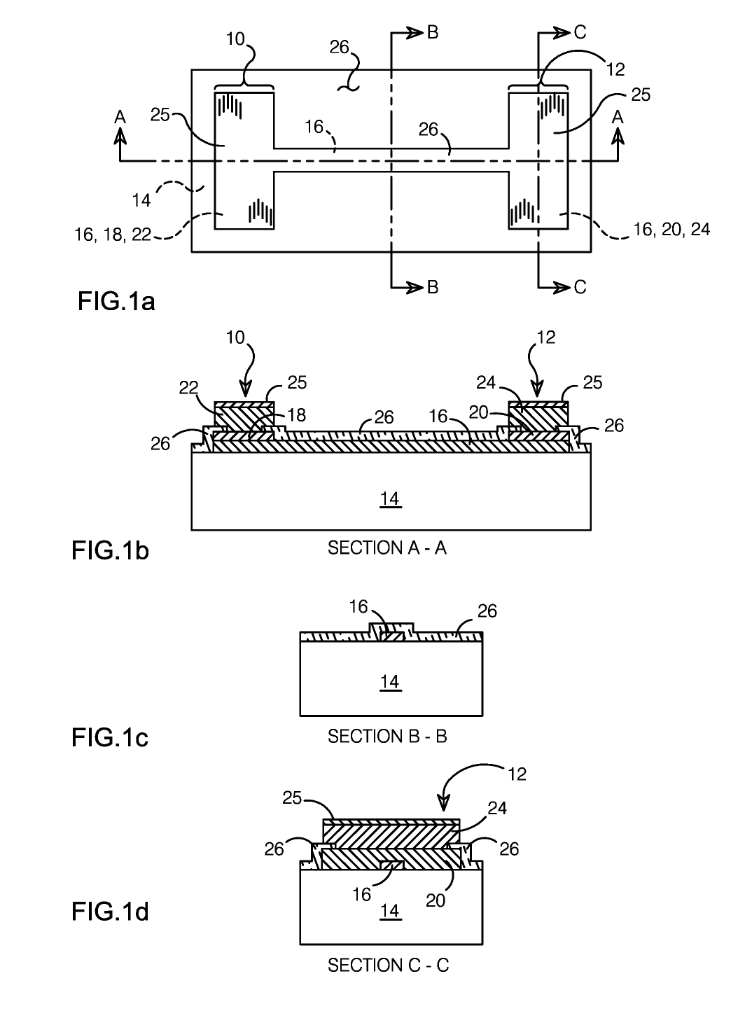

The principles of the invention are illustrated in the plan view of an IC shown in FIG. 1a, along with the cross-sectional views of the IC of FIG. 1a shown in FIGS. 1b, 1c and 1d, which are cut along section lines A-A, B-B and C-C, respectively. In this example, two metallic electrode pads 10, 12 are formed on an IC substrate 14, and interconnected with a thin-film metallic circuit 16. The substrate material may be, for example, ceramic AlN, silicon carbide (SiC), single crystal SiC, or AlₓGa₁₋ₓN (x>0.69). Thin-film metallic circuit 16, which is contiguous with the base layer of electrode pads 10 and 12 in this example, comprises a metal such as tungsten (W). Electrode pads 10 and 12 may also include an optional conductive barrier layer 18, 20, and a top layer 22, 24, to which leads used to connect the pads to external electronics may be attached—by pressure, solder, bonding or welding, for example. To protect the top surfaces of layers 22 and 24, an optional thin layer 25 of a metal such as platinum (Pt) could be used to cover and thereby protect the surfaces.

To protect metallic structures on substrate 14 from oxidation and from reducing and vacuum environments, an AlN thin-film 26 is applied so as to encapsulate at least one of the metallic structures. In the example shown in FIGS. 1a-1d, AlN thin-film 26 encapsulates metallic circuit 16, the edge surfaces of barrier layers 18 and 20 and the base layer of electrode pads 10 and 12, and the top surface of substrate 14. The AlN thin-film can be deposited by thin-film processes such as reactive sputtering or chemical vapor deposition (CVD). Note that, though AlN thin-film 26 is shown covering the entire top surface of substrate 14, it could also be patterned and etched so that only certain features are encapsulated. The AlN thin-film might also be applied over lead wires which provide connections to metallic structures on the substrate, thereby protecting them as well.

Metallic circuit 16 could be, for example, an environmental sensor which produces an output that varies with a physical parameter like temperature or pressure. Environmental sensors of this sort are described, for example, in U.S. Pat. No. 7,106,167 to Parsons. For example, a thin-film of tungsten on a ceramic AlN substrate may be used to sense temperature, since the resistance of the tungsten varies with temperature. However, the transfer function between the circuit's resistance and temperature can vary under certain conditions, such as when the metal thin-film is subjected to an oxidizing atmosphere or to reducing or vacuum environments. However, when an AlN thin-film is employed as shown in FIGS. 1a-1d, metallic circuit 16 and the edge surfaces of barrier layers 18 and 20 and the base layer of electrode pads 10 and 12 are completely encapsulated, and thus protected from exposure to oxide (assuming a temperature of ≦1050° C.—AlN may oxidize at temperatures above 1050° C.) and from reducing atmospheres at temperatures up to 1800° C. (however, AlN may become electrically conductive at temperatures above about 1500° C.). When used to encapsulate only certain features, the AlN thin-film is preferably applied so as to extend over and lateral to the encapsulated structures, such that it at least partially covers the substrate; encapsulating metallic structures in this way helps to secure them to substrate 14.

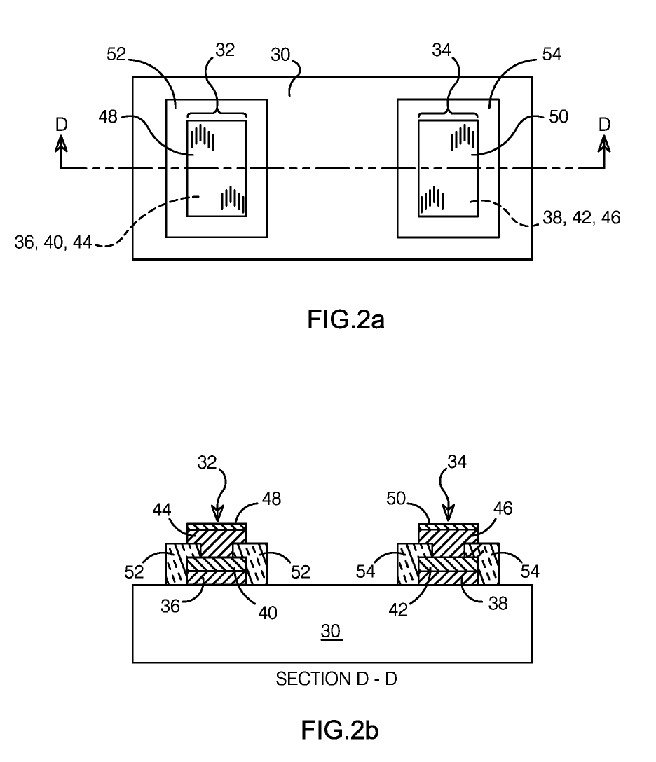

Another possible application of an AlN thin-film in accordance with the present invention is shown in FIGS. 2a and 2b, with FIG. 2a being a plan view of an IC and FIG. 2b being a cross-sectional view of the IC of FIG. 2a, cut along section lines D-D. In this example, the substrate 30 is SiC, single crystal SiC, or AlₓGa₁₋ₓN (x>0.69), and is itself part of the IC circuitry; for example, two physically separated electrode pads in ohmic contact with an SiC substrate provide an SiC resistor. Connection to the substrate material is made via electrodes 32 and 34: in this example, electrodes 32 and 34 comprise metallic base portions 36 and 38, respectively, which form ohmic contacts with substrate 30, optional conductive barrier layers 40 and 42, top layers 44 and 46, and optional Pt thin-films 48 and 50 on top layers 44 and 46.

Stable operation of most ICs requires that the electrical current cross-section through the IC's electrode pads remain constant. This can be ensured by applying AlN thin-films 52, 54 which completely encapsulate all edge surfaces of the electrode pads from exposure to oxide (≦1050° C.) and from reducing atmospheres at temperatures up to 1800° C. In FIGS. 2a and 2b, the AlN thin-film is also applied to the substrate surfaces just beyond the electrode pads, to ensure that the edge surfaces are encapsulated and to help secure the electrode pad layers to the substrate.

An AlN thin-film is well-suited to the encapsulant applications described above, in that the interface between the thin-film and the materials in which the thin-film is in contact remains stable at high temperatures. Thus, though an AlN thin-film forms a mechanical bond with various substrate materials such as ceramic AlN, SiC, single crystal SiC, or AlₓGa₁₋ₓN, as well as with W, the thin-film does not react with or diffuse into these materials.

The thermal stability of these interfaces is important. For example, if W is encapsulated with AlN and the AlN were to further react with W at elevated temperatures, then the electrical conductivity of the W circuit would change (drift); however, because the interface is thermally stable, this does not happen. Similarly, if AlN reacted with the side walls of electrode metals such as titanium carbide or the surface of SiC, the AlN would not be an effective encapsulant because the effective channel length of the SiC would change as the electrode side walls and/or the SiC channel depth changed due to interdiffusion or reaction between AlN and the materials it is supposed to encapsulate.

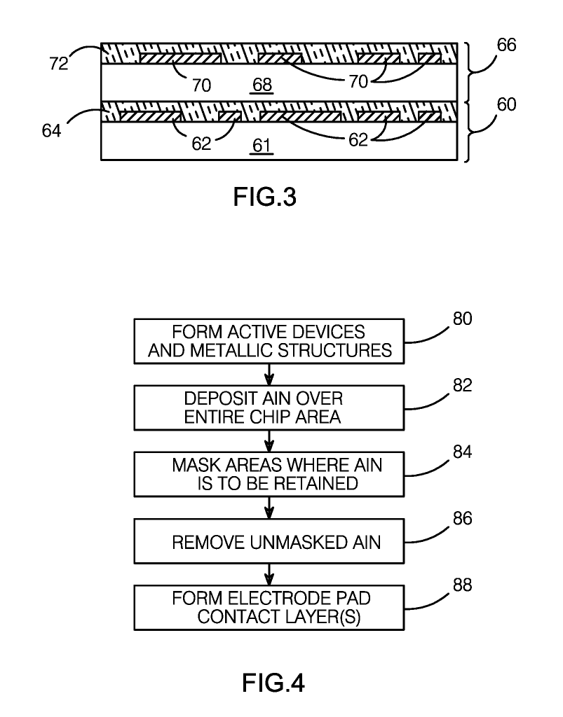

Another possible use for an AlN thin-film as described herein is illustrated in FIG. 3. There is often a need to stack IC layers, each of which contains many devices and metallic structures, in close proximity to each other. This is enabled with the present thin-film: IC layers which support an adjacent IC layer are electrically isolated by interlayers of thin-film AlN. For example, in FIG. 3, a first IC layer 60 comprises a substrate 61 which supports a number of metallic structures 62, and an AlN thin-film 64 which is applied over the entire surface of substrate 61, as well as over metallic structures 62. A second IC layer 66 comprises a substrate 68 which supports metallic structures 70, and is stacked on top of circuit layer 60. AlN thin-film 64 acts to protect metallic structures 62, and to insulate the structures and substrate 61 from layer 66 above it. If an additional IC layer is to be added to the stack, an AlN thin-film 72 would be applied so as to cover the surface of substrate 68 and metallic structures 70. This process is repeated as additional IC layers are stacked. The use of an AlN thin-film as an interlayer could be used with the IC arrangements shown in both FIGS. 1a-1d and 2a-2b.

The encapsulation applications described above represent just a few examples of ways in which the present AlN thin-film could be employed. Additional situations in which the present AlN thin-film might be used (under appropriate thermal and environmental conditions) are described, for example, in U.S. Pat. No. 6,995,691 to Parsons.

One possible process sequence for applying an AlN thin-film per the present invention is shown in FIG. 4. In step 80, the IC's active devices and metallic structures are formed, except for the top electrode pad contact layer (if applicable). An AlN thin-film is then deposited over the entire chip area (step 82), preferably via reactive sputtering or CVD. If less than the entire substrate surface area is to be encapsulated, the next step (84) is to mask all areas where the AlN thin-film is to be retained. Then, the unmasked AlN thin-film is removed (86), preferably by argon ion milling or wet chemical etching. The electrode pad contact layer(s) is then deposited, preferably through a shadow mask or deposited over the entire chip area; if deposited over the entire chip area, the electrode pad contact layer(s) are then masked over pad areas and the unmasked electrode pad contact metal(s) is etched away (88).

The embodiments of the invention described herein are exemplary and numerous modifications, variations and rearrangements can be readily envisioned to achieve substantially equivalent results, all of which are intended to be embraced within the spirit and scope of the invention as defined in the appended claims.

We claim:

1. An integrated circuit (IC), comprising:
a substrate;
at least one metallic structure on said substrate; and
an aluminum nitride (AlN) thin-film applied so as to encapsulate at least one of said metallic structures such that said encapsulated structures are protected from oxidation and from reducing and vacuum environments.

2. The IC of claim 1, wherein said substrate is selected from a group consisting of ceramic AlN, silicon carbide (SiC), single crystal SiC, or AlₓGa₁₋ₓN (x>0.69).

3. The IC of claim 1, wherein said at least one metallic structure comprises thin-film metallic circuitry.

4. The IC of claim 3, wherein said thin-film metallic circuitry comprises an environmental sensor.

5. The IC of claim 4, wherein said sensor produces an output which varies with temperature or pressure.

6. The IC of claim 1, wherein said metallic structure comprises tungsten.

7. The IC of claim 1, wherein said metallic structure comprises at least one electrode pad.

8. The IC of claim 7, wherein at least one of said electrode pads comprises a conductive barrier layer and a metallic top layer on said conductive barrier layer.

9. The IC of claim 8, wherein said metallic top layer comprises tungsten.

10. The IC of claim 8, wherein at least one of said electrode pads further comprises a thin-film of platinum on said metallic top layer.

11. The IC of claim 1, wherein said AlN thin-film is applied so as to extend over and lateral to said encapsulated structures such that it at least partially covers said substrate.

12. The IC of claim 11, wherein said substrate is arranged such that said AlN thin-film which at least partially covers said substrate adheres to said substrate.

13. The IC of claim 1, wherein said encapsulation electrically insulates said encapsulated metallic structures.

14. The IC of claim 1, wherein said AlN thin-film is applied such that it covers the entire surface of said substrate.

15. The IC of claim 14, further comprising one or more additional IC layers stacked on top of said IC, each of said additional IC layers which is below another IC layer having an AlN thin-film covering its entire top surface such that it is separated and electrically insulated from adjacent IC layers.

16. The IC of claim 1, wherein said at least one metallic structure includes lead wires, said AlN thin-film applied so as to at least partially encapsulate said lead wires.

17. The IC of claim 1, wherein said AlN thin-film is further arranged to secure said encapsulated structures to said substrate.

18. An integrated circuit (IC), comprising:
a ceramic aluminum nitride (AlN) substrate;
a base metallic layer arranged to form thin-film metallic circuitry on said substrate;
at least one electrode pad on said substrate, said at least one electrode pad having a top surface and comprising:
a base portion formed by said base metallic layer; and
a thin-film of platinum on said top surface; and
an aluminum nitride (AlN) thin-film applied so as to cover the exposed portions of base metallic layer, the vertical edges of said electrode pads, and said ceramic AlN substrate such that said covered structures are protected from oxidation and from reducing and vacuum environments.

19. The IC of claim 18, wherein said base portion includes a conductive barrier layer.

20. An integrated circuit (IC), comprising:
a substrate made from a material selected from a group consisting of silicon carbide (SiC), single crystal SiC, or AlₓGa₁₋ₓN (x>0.69);
at least one electrode pad on said substrate, said at least one electrode pad having a top surface and comprising:
a base portion which forms an ohmic contact with said substrate; and
a thin-film of platinum on said top surface; and
an aluminum nitride (AlN) thin-film applied so as to cover the vertical edges of said electrode pads and at least a portion of said substrate.

21. The IC of claim 20, wherein said base portion includes a conductive barrier layer.

22. A sensing system, comprising:
a substrate;
an environmental sensor on said substrate;
an aluminum nitride (AlN) thin-film applied so as to encapsulate said sensor such that said sensor is protected from oxidation and from reducing and vacuum environments.

23. The sensing system of claim 22, wherein said environmental sensor produces an output which varies with temperature or pressure.

24. The sensing system of claim 22, wherein said environmental sensor includes lead wires, said AlN thin-film applied so as to at least partially encapsulate said lead wires.

25. A method of encapsulating one or more metallic structures on a substrate, comprising:
forming said metallic structures on said substrate; and
depositing aluminum nitride (AlN) on said substrate so as to form a thin-film which encapsulates at least one of said metallic structures such that said encapsulated structures are protected from oxidation and from reducing and vacuum environments.

26. The method of claim 25, wherein said AlN is deposited by reactive sputtering or by chemical vapor deposition (CVD).

27. The method of claim 25, wherein said AlN is deposited such that it covers the entire surface of said substrate.

28. The method of claim 25, wherein said AlN is applied so as to extend over and lateral to said encapsulated structures such that it at least partially covers said substrate.

29. The method of claim 25, further comprising:
providing additional substrates;
forming one or more metallic structures on said additional substrates;
depositing AlN on at least some of said additional substrates such that it covers the entire surfaces of said substrates; and
stacking said additional substrates on top of said substrate, said AlN thin-film separating and electrically insulating said additional substrates from adjacent substrates.

30. A method of encapsulating one or more metallic structures on a substrate, comprising:
forming said metallic structures on said substrate;
depositing aluminum nitride (AlN) on said substrate so as to form a thin-film over said substrate's entire surface area;
masking the metallic structures which are to be encapsulated;
removing said AlN thin-film from the portions of said substrate which are unmasked; and
forming electrode pad contact areas if needed;
such that said encapsulated structures are protected from oxidation and from reducing and vacuum environments.

31. The method of claim 30, wherein said unmasked AlN thin-film is removed by argon ion milling or wet chemical etching.

32. The method of claim 30, wherein said electrode pad contact areas are formed by depositing a metal through a shadow mask.

33. The method of claim 30, wherein said electrode pad contact areas are formed by:
depositing a metal layer over the entire substrate area;
masking said electrode pad contact areas; and
removing said metal from the portions of said substrate which are unmasked.
